(19) United States
(12) Patent Application Publication
(10) Pub. No.: US 2025/0084529 A1
(43) Pub. Date: Mar. 13, 2025

(54) HEAT TRANSFER MANAGEMENT IN SUBSTRATE SUPPORT SYSTEMS

(71) Applicant: Applied Materials, Inc., Santa Clara, CA (US)

(72) Inventor: Arvinder ManmohanSingh Chadha, San Jose, CA (US)

(21) Appl. No.: 18/244,199

(22) Filed: Sep. 8, 2023

(51) Int. Cl. C23C 14/54; F28F 27/00

(52) U.S. Cl. CPC C23C 14/541; F28F 27/00

(57) ABSTRACT

A method includes: identifying property data associated with a substrate support system; identifying target performance data associated with the substrate support system; determining, based on the property data and the target performance data, zone configuration data associated with the substrate support system; and causing the substrate support system to be configured based on the zone configuration data.

### TECHNICAL FIELD

The present disclosure relates to management in manufacturing systems, such as substrate support systems, and in particular to heat transfer management in a manufacturing system.

### BACKGROUND

Products are produced by performing one or more manufacturing processes using manufacturing equipment. For example, substrate processing equipment is used to process substrates by performing processes on substrates in processing chambers.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a method includes: identifying property data associated with a substrate support system; identifying target performance data associated with the substrate support system; and causing, based on the property data and the target performance data, heat transfer management of the substrate support system.

In another aspect of the disclosure, a non-transitory machine-readable storage medium storing instructions which, when executed cause a processing device to perform operations including: identifying property data associated with a substrate support system; identifying target performance data associated with the substrate support system; and causing, based on the property data and the target performance data, performance of one or more material operations on the substrate support system.

In another aspect of the disclosure, a system includes memory and a processing device coupled to the memory. The processing device is to: identify property data associated with a substrate support system; identify target performance data associated with the substrate support system; and cause, based on the property data and the target performance data, performance of one or more material operations on the substrate support system.

In an aspect of the disclosure, a method includes: identifying property data associated with a substrate support system; identifying target performance data associated with the substrate support system; determining, based on the property data and the target performance data, zone configuration data associated with the substrate support system; and causing the substrate support system to be configured based on the zone configuration data.

In another aspect of the disclosure, a non-transitory machine-readable storage medium storing instructions which, when executed cause a processing device to perform operations including: identifying property data associated with a substrate support system; identifying target performance data associated with the substrate support system; determining, based on the property data and the target performance data, zone configuration data associated with the substrate support system; and causing the substrate support system to be configured based on the zone configuration data.

In another aspect of the disclosure, a system includes memory and a processing device coupled to the memory. The processing device is to: identify property data associated with a substrate support system; identify target performance data associated with the substrate support system; determine, based on the property data and the target performance data, zone configuration data associated with the substrate support system; and cause the substrate support system to be configured based on the zone configuration data.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to certain embodiments.

FIG. 2 illustrates a data set generator to create data sets for a machine learning model, according to certain embodiments.

FIG. 3 is a block diagram illustrating determining predictive data, according to certain embodiments.

FIGS. 4A-F are flow diagrams of methods associated with heat transfer management, according to certain embodiments.

FIGS. 5A-U illustrate portions of substrate support systems, according to certain embodiments.

FIG. 6 is a block diagram illustrating a computer system, according to certain embodiments.

### DETAILED DESCRIPTION

Described herein are technologies directed to heat transfer management in substrate support systems (e.g., wafer support systems).

Products are produced by performing one or more manufacturing processes using manufacturing equipment. For example, substrate processing equipment is used to process substrates by performing processes on substrates in processing chambers. Processes performed on substrates can include one or more of plasma operations chemical vapor deposition (CVD) operations, atomic layer deposition (ALD) operations, physical vapor deposition (PVD) operations, plasma enhanced chemical vapor deposition (PECVD) operations, sputtering operations, eBeam operations, thermal evaporation operations, heating operations, cooling operations, and so forth.

Conventionally, during processes performed on substrates, heat transfer with the substrate is not precisely controlled. This can be caused by conventional cooling channels providing inadequate heat transfer coefficient of the coolant to the cooling base and/or conventional heaters being inadequate to compensate for azimuthal non-uniformity. This inability to precisely perform heat transfer management (e.g., inadequate wafer thermal uniformity) can cause poor substrate quality, reduced yield, use of expensive equipment to try to more precisely perform heat transfer management, and so forth.

The devices, systems, and methods disclosed herein provide solutions to these and other shortcomings of conventional systems.

A processing device identifies property data associated with a substrate support system. In some embodiments, the substrate support system is an electrostatic chuck (ESC) stack that includes layers, such as a ceramic puck, a cooling plate, and bond material that bonds the ceramic puck to the cooling plate. The ceramic puck may include heaters, a clamp electrode, gas channels, etc. The cooling plate may include cooling channels, gas channels, etc. The property data may correspond to measurement data (e.g., thicknesses, widths, spacing, sizes, etc.) of components of the substrate support system.

The processing device further identifies target performance data associated with the substrate support system. The target performance data may be a target heat map or etch depth map or deposition thickness map of an upper surface of the substrate support system. In some embodiments, the target heat map is a substantially uniform heat map (e.g., substantially same temperature at all points on the upper surface of the substrate support system). In some embodiments, the target heat map is an intentional non-uniform heat map (e.g., a first portion of the upper surface is at a first temperature and a second portion of the upper surface is at a second temperature that is different from the first temperature). The target performance data may be one or more target temperatures of the upper surface of the substrate support system. The target performance data may be one or more target temperatures of a substrate disposed on the upper surface of the substrate support system.

The processing device further causes, based on the property data and the target performance data, heat transfer management of the substrate support system. In some embodiments, the processing device uses a trained machine learning model that is trained using data input of historical property data and historical target performance data and target output of historical heat transfer management data. The processing device provides the property data and the target performance data as input to the trained machine learning model and determines heat transfer management data based on predictive data associated with output of the trained machine learning model. The causing of the heat transfer management may be based on the heat transfer management data.

In some embodiments, to cause heat transfer management, the processing device causes performance of one or more material operations on the substrate support system. Material operations may include one or more of removing material, adding material, processing surfaces, etc. For example, material operations may include adding material to a first portion of the upper surface of the substrate support system, removing material from a second portion of the upper surface of the substrate support system, and/or roughening (e.g., corrugating) surfaces (e.g., channel surfaces, outer surfaces) of the substrate support system.

In some embodiments, to cause heat transfer management, the processing device determines, based on the property data and the target performance data, zone configuration data associated with the substrate support system and causes the substrate support system to be configured based on the zone configuration data. In some embodiments, a zone can be annulus-shaped (e.g., a ring, has an outer circumference and an inner circumference), disc-shaped (e.g., substantially circular), or segment shaped (e.g., formed by different segments, multiple segments that form a ring or disc, etc.). In some embodiments, causing the substrate support system to be configured based on the zone configuration data includes causing the substrate support system to be manufactured based on the zone configuration data. This may include causing the substrate support system to have one or more continuous heaters and one or more pixelated heaters. In some embodiments, causing the substrate support system to be configured based on the zone configuration data includes causing the substrate support system to be controlled based on the zone configuration data. This may include causing one or more continuous heaters and/or one or more pixelated heaters to be controlled.

Aspects of the present disclosure result in technological advantages. The present disclosure allows more precise heat transfer management of (e.g., more precise heat transfer with) a substrate during processes performed on substrates than conventional systems. The present disclosure allows more accurate substrate thermal uniformity or more accurate heat map than conventional systems. This causes better substrate quality, increased yield, reduced use (or eliminated use) of expensive equipment to perform heat transfer management, etc.

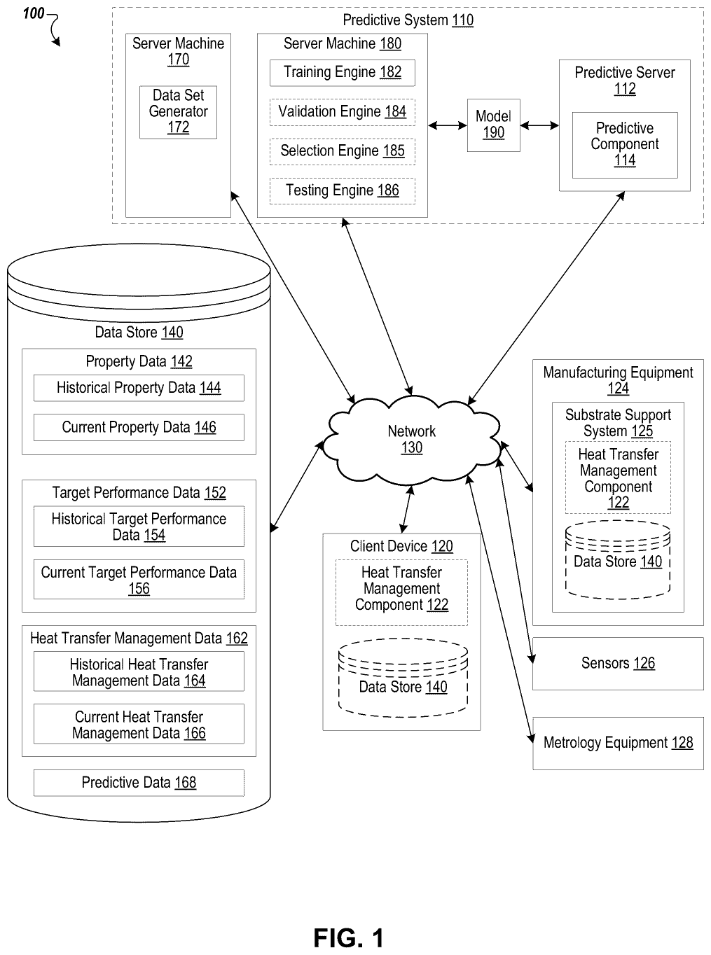

FIG. 1 is a block diagram illustrating an exemplary system 100 (exemplary system architecture), according to certain embodiments. The system 100 includes a client device 120, manufacturing equipment 124, sensors 126, metrology equipment 128, a predictive server 112, and a data store 140. In some embodiments, the predictive server 112 is part of a predictive system 110. In some embodiments, the predictive system 110 further includes server machines 170 and 180.

In some embodiments, one or more of the client device 120, manufacturing equipment 124, sensors 126, metrology equipment 128, predictive server 112, data store 140, server machine 170, and/or server machine 180 are coupled to each other via a network 130 for generating predictive data 168 to perform heat transfer management. In some embodiments, network 130 is a public network that provides client device 120 with access to the predictive server 112, data store 140, and other publicly available computing devices. In some embodiments, network 130 is a private network that provides client device 120 access to manufacturing equipment 124, sensors 126, metrology equipment 128, data store 140, and other privately available computing devices. In some embodiments, network 130 includes one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

In some embodiments, client device 120 and/or substrate support system 125 includes heat transfer management component 122 and/or a data store 140. The data store 140 may be a data storage chip, a printed circuit board (PCB) that has memory, such as random-access memory (RAM)), and/or the like. The heat transfer management component 122 and/or data store 140 may be used to one or more of control heaters (e.g., pixelated heaters and/or continuous heaters), perform predictive calculations, and/or change set points of the heaters (e.g., multizone heaters).

In some embodiments, the client device 120 includes a computing device such as Personal Computers (PCs), laptops, mobile phones, smart phones, tablet computers, netbook computers, etc. In some embodiments, the client device 120 includes a heat transfer management component 122. In some embodiments, the heat transfer management component 122 may also be included in the predictive system 110 (e.g., machine learning processing system). In some embodiments, the heat transfer management component 122 is alternatively included in the predictive system 110 (e.g., instead of being included in client device 120). Client device 120 includes an operating system that allows users to one or more of consolidate, generate, view, or edit data, provide directives to the predictive system 110 (e.g., machine learning processing system), etc.

In some embodiments, heat transfer management component 122 receives one or more of user input (e.g., via a Graphical User Interface (GUI) displayed via the client device 120), receives property data 142, receives target performance data 152, receives heat transfer management data 162, etc. In some embodiments, the heat transfer management component 122 transmits the data (e.g., user input, property data 142 and target performance data 152, heat transfer management data 162, etc.) to the predictive system 110, receives predictive data 168 from the predictive system 110, and causes heat transfer management of substrate support system 125 of manufacturing equipment 124 based on the predictive data 168. In some embodiments, the heat transfer management component 122 stores data (e.g., user input, property data 142 and target performance data 152, heat transfer management data 162, etc.) in the data store 140 and the predictive server 112 retrieves data from the data store 140. In some embodiments, the predictive server 112 stores output (e.g., predictive data 168) of the trained machine learning model 190 in the data store 140 and the client device 120 retrieves the output from the data store 140. In some embodiments, the heat transfer management component 122 receives an indication of heat transfer management (e.g., based on predictive data 168) from the predictive system 110 and causes heat transfer management of the substrate support system 125.

In some embodiments, the predictive data 168 is associated with heat transfer management (e.g., heat transfer management data 162). In some embodiments, heat transfer management is associated with one or more of performance of one or more material operations on the substrate support system (e.g., removing material, adding material, processing surfaces, etc.), causing the substrate support system to be configured (e.g., manufactured, controlled, etc.), and/or the like.

In some embodiments, a corrective action is performed based on the heat transfer management data 162. In some embodiments, the corrective action includes providing an alert (e.g., an alarm to not use the substrate processing equipment part or the manufacturing equipment 124 if the predictive data 168 indicates a predicted non-compliance with desired performance data). In some embodiments, the corrective action includes providing feedback control (e.g., cleaning, repairing, adding material to, removing material from, processing, and/or replacing a substrate processing equipment part responsive to the predictive data 168 indicating a predicted non-compliance). In some embodiments, the corrective action includes providing machine learning (e.g., determining a heat transfer management data 162 based on the predictive data 168).

In some embodiments, the predictive server 112, server machine 170, and server machine 180 each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

The predictive server 112 includes a predictive component 114. In some embodiments, the predictive component 114 receives property data 142 and target performance data 152 (e.g., receive from the client device 120, retrieve from the data store 140) and generates predictive data 168 associated with a heat transfer management data (e.g., heat transfer management). In some embodiments, the predictive component 114 uses one or more trained machine learning models 190 to determine the predictive data 168 for heat transfer management. In some embodiments, trained machine learning model 190 is trained using historical property data 144, historical target performance data 154, and historical heat transfer management data 164.

In some embodiments, the predictive system 110 (e.g., predictive server 112, predictive component 114) generates predictive data 168 using supervised machine learning (e.g., supervised data set, historical property data 144 and historical target performance data 154 labeled with historical heat transfer management data 164, etc.). In some embodiments, the predictive system 110 generates predictive data 168 using semi-supervised learning (e.g., semi-supervised data set, heat transfer management data 162 is a predictive percentage, etc.). In some embodiments, the predictive system 110 generates predictive data 168 using unsupervised machine learning (e.g., unsupervised data set, clustering, clustering based on historical property data 144 and historical target performance data 154, etc.).

In some embodiments, the manufacturing equipment 124 (e.g., cluster tool) is part of a substrate processing system (e.g., integrated processing system). The manufacturing equipment 124 includes one or more of a substate support system 125, a controller, an enclosure system (e.g., substrate carrier, front opening unified pod (FOUP), auto teach FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers, a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafer, etc.) between the load lock, the processing chambers, and the transfer chamber.

In some embodiments, the sensors 126 provide sensor data (e.g., sensor values, such as historical sensor values and current sensor values) associated with manufacturing equipment 124. In some embodiments, the sensors 126 include one or more of an imaging sensor (e.g., camera, image capturing device, etc.), a pressure sensor, a temperature sensor, a flow rate sensor, a spectroscopy sensor, and/or the like. In some embodiments, the sensor data used for equipment health and/or product health (e.g., product quality). In some embodiments, the sensor data is received over a period of time. In some embodiments, sensors 126 provide sensor data such as values of one or more of image data, leak rate, temperature, pressure, flow rate (e.g., gas flow), pumping efficiency, spacing (SP), High Frequency Radio Frequency (HFRF), electrical current, power, voltage, and/or the like. In some embodiments, the property data 142 and target performance data 152 and/or heat transfer management data 162 includes sensor data from one or more of sensors 126.

In some embodiments, the property data 142 and/or target performance data 152 (e.g., historical property data 144 and historical target performance data 154, current property data 146 and current target performance data 156, etc.) are processed by the client device 120 and/or by the predictive server 112. In some embodiments, processing of the property data 142 and target performance data 152 includes generating features. In some embodiments, the features are a portion of the property data 142 and/or target performance data 152 (e.g., dimensions, heat map, etc.), pattern in the property data 142 and target performance data 152 (e.g., repetition of dimensions, heat map, etc.), or a combination of values from the property data 142 and target performance data 152 (e.g., ratio of dimensions, etc.). In some embodiments, the property data 142 and target performance data 152 include features that are used by the predictive component 114 for obtaining predictive data 168.

In some embodiments, the metrology equipment 128 (e.g., imaging equipment, spectroscopy equipment, ellipsometry equipment, etc.) is used to determine metrology data (e.g., inspection data, image data, spectroscopy data, ellipsometry data, material compositional, optical, or structural data, etc.) corresponding to substrates produced by the manufacturing equipment 124 (e.g., substrate processing equipment). In some examples, after the manufacturing equipment 124 processes substrates, the metrology equipment 128 is used to inspect portions (e.g., layers) of the substrates. In some embodiments, the metrology equipment 128 performs scanning acoustic microscopy (SAM), ultrasonic inspection, x-ray inspection, and/or computed tomography (CT) inspection. In some examples, after the manufacturing equipment 124 deposits one or more layers on a substrate, the metrology equipment 128 is used to determine quality of the processed substrate (e.g., thicknesses of the layers, uniformity of the layers, interlayer spacing of the layer, and/or the like). In some embodiments, the metrology equipment 128 includes an image capturing device (e.g., SAM equipment, ultrasonic equipment, x-ray equipment, CT equipment, and/or the like).

In some embodiments, the data store 140 is memory (e.g., random access memory), a drive (e.g., a hard drive, a flash drive), a database system, or another type of component or device capable of storing data. In some embodiments, data store 140 includes multiple storage components (e.g., multiple drives or multiple databases) that span multiple computing devices (e.g., multiple server computers). In some embodiments, the data store 140 stores one or more of property data 142, target performance data 152, heat transfer management data 162, and/or predictive data 168.

Property data 142 includes historical property data 144 and historical target performance data 154 and current property data 146 and current target performance data 156. In some embodiments, property data 142 may include one or more of thicknesses, widths, spacing, sizes, etc. of substrate support systems. A substrate support system may include a ceramic puck (e.g., electrostatic puck) and a cooling plate that are bonded together. The ceramic puck may include a clamp electrode, heaters, gas channels, etc. The cooling plate may form cooling channels and gas channels.

Target performance data 152 includes historical target performance data 154 and current target performance data 156. The target performance data 152 may include a heat map of an upper surface of the substrate support system (e.g., upper surface of ceramic puck, surface on which substrate is to be disposed).

Heat transfer management data 162 includes historical heat transfer management data 164 and current heat transfer management data 166. Heat transfer management data 162 may include one or more material operations (e.g., material removal, material addition, material processing) of the substrate support system, zone configuration data, etc. In some embodiments, zone configuration data is associated with manufacturing of zones of the substrate support system (e.g., 3D printing of components that form channels, green sheet manufacturing of components that form channels, etc.). In some embodiments, zone configuration data is associated with control the zones of the substrate support system (e.g., duty, cycle, and/or voltage to each of the zones, tune heaters azimuthally) to achieve a desired set point temperature (e.g., in a predetermined or shortest amount of time).

In some embodiments, historical data includes one or more of historical property data 144, historical target performance data 154, and/or historical heat transfer management data 164 (e.g., at least a portion for training the machine learning model 190). Current data includes one or more of current property data 146, current target performance data 156, and/or current heat transfer management data 166 (e.g., at least a portion to be input into the trained machine learning model 190 subsequent to training the model 190 using the historical data). In some embodiments, the current data is used for retraining the trained machine learning model 190.

In some embodiments, the predictive data 168 is to be used for heat transfer management (e.g., predictive heat transfer management data, cause substrates to be processed based on heat transfer management data).

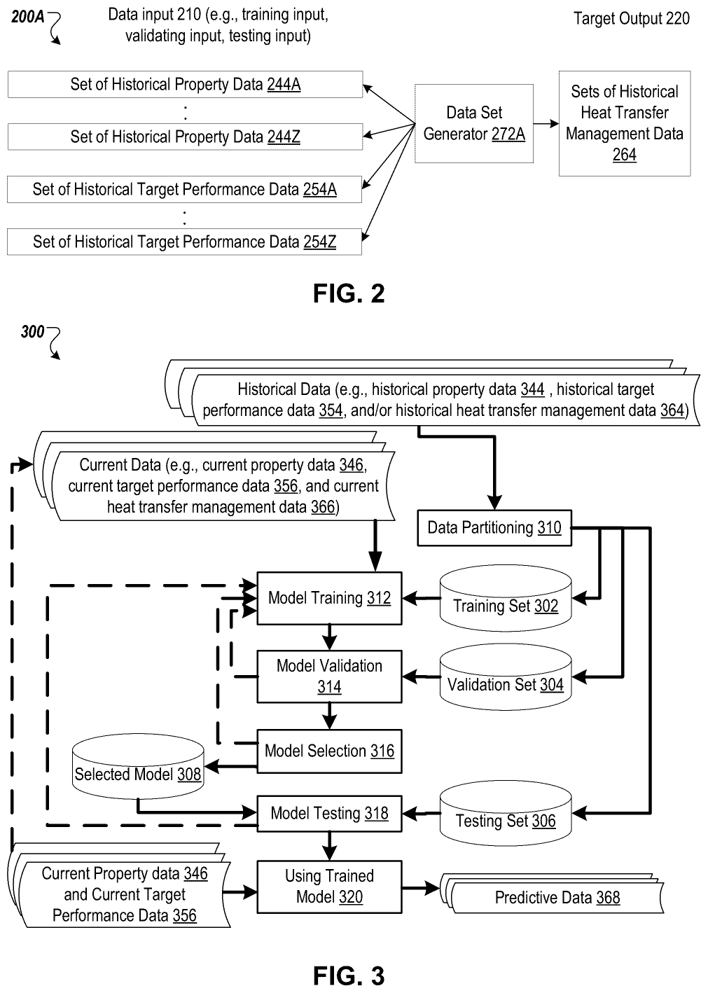

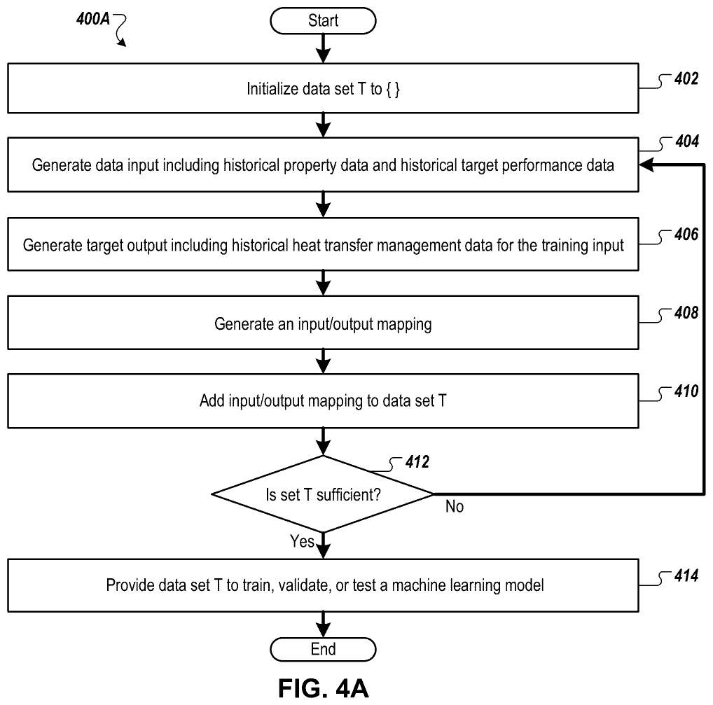

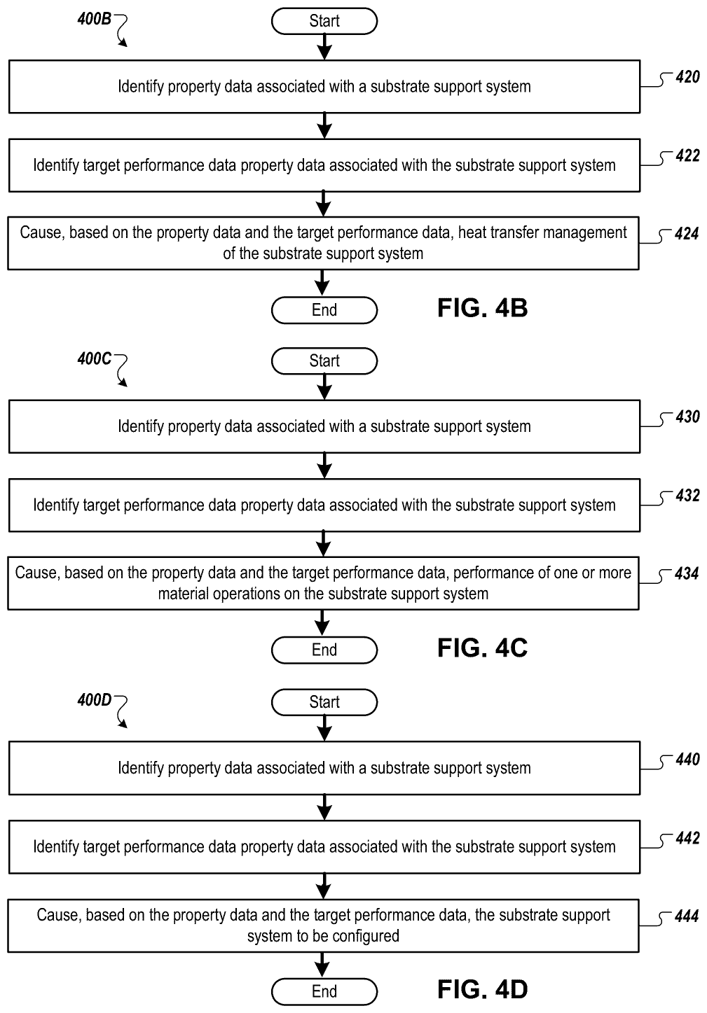

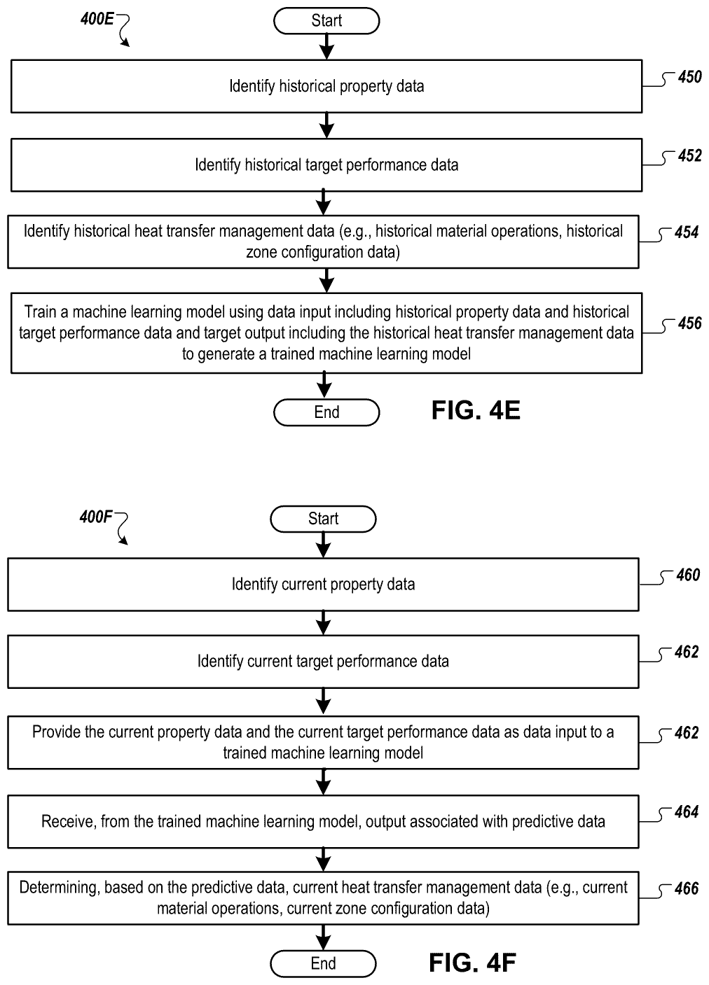

In some embodiments, predictive system 110 further includes server machine 170 and server machine 180. Server machine 170 includes a data set generator 172 that is capable of generating data sets (e.g., a set of data inputs and a set of target outputs) to train, validate, and/or test a machine learning model(s) 190. The data set generator 172 has functions of data gathering, compilation, reduction, and/or partitioning to put the data in a form for machine learning. In some embodiments (e.g., for small datasets), partitioning (e.g., explicit partitioning) for post-training validation is not used. Repeated cross-validation (e.g., 5-fold cross-validation, leave-one-out-cross-validation) may be used during training where a given dataset is in-effect repeatedly partitioned into different training and validation sets during training. A model (e.g., the best model, the model with the highest accuracy, etc.) is chosen from vectors of models over automatically-separated combinatoric subsets. In some embodiments, the data set generator 172 may explicitly partition the historical data (e.g., historical property data 144, historical target performance data 154, and corresponding historical heat transfer management data 164) into a training set (e.g., sixty percent of the historical data), a validating set (e.g., twenty percent of the historical data), and a testing set (e.g., twenty percent of the historical data). In this embodiment, some operations of data set generator 172 are described in detail below with respect to FIGS. 2 and 4A. In some embodiments, the predictive system 110 (e.g., via predictive component 114) generates multiple sets of features (e.g., training features). In some examples a first set of features corresponds to a first set of types of property data 142 and target performance data 152 (e.g., first types of operations, associated with a first set of sensors, first combination of values, first patterns in the values) that correspond to each of the data sets (e.g., training set, validation set, and testing set) and a second set of features correspond to a second set of types of property data 142 and target performance data 152 (e.g., second types of operations, associated with a second set of sensors different from the first set of sensors, second combination of values different from the first combination, second patterns different from the first patterns) that correspond to each of the data sets.

Server machine 180 includes a training engine 182, a validation engine 184, selection engine 185, and/or a testing engine 186. In some embodiments, an engine (e.g., training engine 182, a validation engine 184, selection engine 185, and a testing engine 186) refers to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 is capable of training a machine learning model 190 using one or more sets of features associated with the training set from data set generator 172. In some embodiments, the training engine 182 generates multiple trained machine learning models 190, where each trained machine learning model 190 corresponds to a distinct set of parameters of the training set (e.g., property data 142 and target performance data 152) and corresponding responses (e.g., heat transfer management data 162). In some embodiments, multiple models are trained on the same parameters with distinct targets for the purpose of modeling multiple effects. In some examples, a first trained machine learning model was trained using property data 142 and target performance data 152 for all substrate support systems (e.g., substrate support systems 1-5), a second trained machine learning model was trained using a first subset of the property data 142 and target performance data 152 (e.g., substrate support systems 1, 2, and 4), and a third trained machine learning model was trained using a second subset of the property data 142 and target performance data 152 (e.g., substrate support systems 1, 3, 4, and 5) that partially overlaps the first subset of features.

The validation engine 184 is capable of validating a trained machine learning model 190 using a corresponding set of features of the validation set from data set generator 172. For example, a first trained machine learning model 190 that was trained using a first set of features of the training set is validated using the first set of features of the validation set. The validation engine 184 determines an accuracy of each of the trained machine learning models 190 based on the corresponding sets of features of the validation set. The validation engine 184 evaluates and flags (e.g., to be discarded) trained machine learning models 190 that have an accuracy that does not meet a threshold accuracy. In some embodiments, the selection engine 185 is capable of selecting one or more trained machine learning models 190 that have an accuracy that meets a threshold accuracy. In some embodiments, the selection engine 185 is capable of selecting the trained machine learning model 190 that has the highest accuracy of the trained machine learning models 190.

The testing engine 186 is capable of testing a trained machine learning model 190 using a corresponding set of features of a testing set from data set generator 172. For example, a first trained machine learning model 190 that was trained using a first set of features of the training set is tested using the first set of features of the testing set. The testing engine 186 determines a trained machine learning model 190 that has the highest accuracy of all of the trained machine learning models based on the testing sets.

In some embodiments, the machine learning model 190 (e.g., used for classification) refers to a model artifact that is created by the training engine 182 using a training set that includes data inputs and corresponding target outputs (e.g., correctly classifies a condition or ordinal level for respective training inputs). Patterns in the data sets can be found that map the data input to the target output (the correct classification or level), and the machine learning model 190 is provided mappings that captures these patterns. In some embodiments, the machine learning model 190 uses one or more of Gaussian Process Regression (GPR), Gaussian Process Classification (GPC), Bayesian Neural Networks, Neural Network Gaussian Processes, Deep Belief Network, Gaussian Mixture Model, or other Probabilistic Learning methods. Non probabilistic methods may also be used including one or more of Support Vector Machine (SVM), Radial Basis Function (RBF), clustering, Nearest Neighbor algorithm (k-NN), linear regression, random forest, neural network (e.g., artificial neural network), etc. In some embodiments, the machine learning model 190 is a multi-variate analysis (MVA) regression model.

Predictive component 114 provides current property data 146 and current target performance data 156 (e.g., as input) to the trained machine learning model 190 and runs the trained machine learning model 190 (e.g., on the input to obtain one or more outputs). The predictive component 114 is capable of determining (e.g., extracting) predictive data 168 from the trained machine learning model 190 and determines (e.g., extracts) uncertainty data that indicates a level of credibility that the predictive data 168 corresponds to current heat transfer management data 166. In some embodiments, the predictive component 114 or heat transfer management component 122 use the uncertainty data (e.g., uncertainty function or acquisition function derived from uncertainty function) to decide whether to use the predictive data 168 to perform a corrective action or whether to further train the model 190.

For purpose of illustration, rather than limitation, aspects of the disclosure describe the training of one or more machine learning models 190 using historical data (i.e., prior data, historical property data 144, historical target performance data 154 and historical heat transfer management data 164) and providing current property data 146 and current target performance data 156 into the one or more trained probabilistic machine learning models 190 to determine predictive data 168. In other implementations, a heuristic model or rule-based model is used to determine predictive data 168 (e.g., without using a trained machine learning model). In other implementations non-probabilistic machine learning models may be used. Predictive component 114 monitors historical property data 144, historical target performance data 154, and historical heat transfer management data 164. In some embodiments, any of the information described with respect to data inputs 210 of FIG. 2 are monitored or otherwise used in the heuristic or rule-based model.

In some embodiments, the functions of client device 120, predictive server 112, server machine 170, and server machine 180 are be provided by a fewer number of machines. For example, in some embodiments, server machines 170 and 180 are integrated into a single machine, while in some other embodiments, server machine 170, server machine 180, and predictive server 112 are integrated into a single machine. In some embodiments, client device 120 and predictive server 112 are integrated into a single machine.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 determines corrective actions based on the predictive data 168. In another example, client device 120 determines the predictive data 168 based on data received from the trained machine learning model.

In addition, the functions of a particular component can be performed by different or multiple components operating together. In some embodiments, one or more of the predictive server 112, server machine 170, or server machine 180 are accessed as a service provided to other systems or devices through appropriate application programming interfaces (API).

In some embodiments, a “user” is represented as a single individual. However, other embodiments of the disclosure encompass a “user” being an entity controlled by a plurality of users and/or an automated source. In some examples, a set of individual users federated as a group of administrators is considered a “user.”

Although embodiments of the disclosure are discussed in terms of determining predictive data 168 for heat transfer management of substrate support systems in manufacturing facilities (e.g., substrate processing facilities), in some embodiments, the disclosure can also be generally applied to heat transfer management. Embodiments can be generally applied to determining heat transfer management based on different types of data.

FIG. 2 illustrates a data set generator 272 (e.g., data set generator 172 of FIG. 1) to create data sets for a machine learning model (e.g., model 190 of FIG. 1), according to certain embodiments. In some embodiments, data set generator 272 is part of server machine 170 of FIG. 1. The data sets generated by data set generator 272 of FIG. 2 may be used to train a machine learning model (e.g., see FIG. 4E) to provide heat transfer management of a substrate support system (e.g., see FIG. 4F).

Data set generator 272 (e.g., data set generator 172 of FIG. 1) creates data sets for a machine learning model (e.g., model 190 of FIG. 1). Data set generator 272 creates data sets using historical property data 244 and historical target performance data 254 (e.g., historical property data 144 and historical target performance data 154 of FIG. 1) and historical heat transfer management data 264 (e.g., historical heat transfer management data 164 of FIG. 1). System 200 of FIG. 2 illustrates data set generator 272, data inputs 210, and target output 220 (e.g., target data).

In some embodiments, data set generator 272 generates a data set (e.g., training set, validating set, testing set) that includes one or more data inputs 210 (e.g., training input, validating input, testing input) and one or more target outputs 220 that correspond to the data inputs 210. The data set also includes mapping data that maps the data inputs 210 to the target outputs 220. Data inputs 210 are also referred to as “features,” “attributes,” or information.” In some embodiments, data set generator 272 provides the data set to the training engine 182, validating engine 184, or testing engine 186, where the data set is used to train, validate, or test the machine learning model 190. Some embodiments of generating a training set are further described with respect to FIG. 4A.

In some embodiments, data set generator 272 generates the data input 210 and target output 220. In some embodiments, data inputs 210 include one or more sets of historical property data 244 and historical target performance data 254. In some embodiments, historical property data 244 and historical target performance data 254 includes one or more operations (e.g., associated with sensor data from one or more types of sensors, combination of sensor data from one or more types of sensors, patterns from sensor data from one or more types of sensors, and/or the like).

In some embodiments, data set generator 272 generates a first data input corresponding to a first set of historical property data 244A and historical target performance data 254A to train, validate, or test a first machine learning model and the data set generator 272 generates a second data input corresponding to a second set of historical property data 244B and historical target performance data 254B to train, validate, or test a second machine learning model.

In some embodiments, the data set generator 272 discretizes (e.g., segments) one or more of the data input 210 or the target output 220 (e.g., to use in classification algorithms for regression problems). Discretization (e.g., segmentation via a sliding window) of the data input 210 or target output 220 transforms continuous values of variables into discrete values. In some embodiments, the discrete values for the data input 210 indicate discrete historical property data 244 and historical target performance data 254 to obtain a target output 220 (e.g., discrete historical heat transfer management data 264).

Data inputs 210 and target outputs 220 to train, validate, or test a machine learning model include information for a particular facility (e.g., for a particular substrate manufacturing facility). In some examples, historical property data 244, historical target performance data 254, and historical heat transfer management data 264 are for the same manufacturing facility.

In some embodiments, the information used to train the machine learning model is from specific types of manufacturing equipment 124 of the manufacturing facility having specific characteristics and allow the trained machine learning model to determine outcomes for a specific group of manufacturing equipment 124 based on input for current parameters (e.g., current property data 146 and current target performance data 156) associated with one or more components sharing characteristics of the specific group. In some embodiments, the information used to train the machine learning model is for components from two or more manufacturing facilities and allows the trained machine learning model to determine outcomes for components based on input from one manufacturing facility.

In some embodiments, subsequent to generating a data set and training, validating, or testing a machine learning model 190 using the data set, the machine learning model 190 is further trained, validated, or tested (e.g., current heat transfer management data 166 of FIG. 1) or adjusted (e.g., adjusting weights associated with input data of the machine learning model 190, such as connection weights in a neural network).

FIG. 3 is a block diagram illustrating a system 300 for generating predictive data 368 (e.g., predictive data 168 of FIG. 1), according to certain embodiments. The system 300 is used to determine predictive data 368 via a trained machine learning model (e.g., model 190 of FIG. 1) for heat transfer management of substrate support systems.

At block 310, the system 300 (e.g., predictive system 110 of FIG. 1) performs data partitioning (e.g., via data set generator 172 of server machine 170 of FIG. 1) of the historical data (e.g., historical property data 344 and historical target performance data 354 and historical heat transfer management data 364 for model 190 of FIG. 1) to generate the training set 302, validation set 304, and testing set 306. In some examples, the training set is 60% of the historical data, the validation set is 20% of the historical data, and the testing set is 20% of the historical data. The system 300 generates a plurality of sets of features for each of the training set, the validation set, and the testing set. In some examples, if the historical data includes features derived from 20 substrate processing systems and 100 heat maps (e.g., heat maps of the 20 substrate processing systems), a first set of features is substrate processing systems 1-10, a second set of features is substrate processing systems 11-20, the training set is heat maps 1-60, the validation set is heat maps 61-80, and the testing set is heat maps 81-100. In this example, the first set of features of the training set would be parameters from substrate processing systems 1-10 for heat maps 1-60.

At block 312, the system 300 performs model training (e.g., via training engine 182 of FIG. 1) using the training set 302. In some embodiments, the system 300 trains multiple models using multiple sets of features of the training set 302 (e.g., a first set of features of the training set 302, a second set of features of the training set 302, etc.). For example, system 300 trains a machine learning model to generate a first trained machine learning model using the first set of features in the training set (e.g., substrate processing systems 1-10 and heat maps 1-60) and to generate a second trained machine learning model using the second set of features in the training set (e.g., substrate processing systems 11-20 and heat maps 1-60). In some embodiments, the first trained machine learning model and the second trained machine learning model are combined to generate a third trained machine learning model (e.g., which is a better predictor than the first or the second trained machine learning model on its own in some embodiments). In some embodiments, sets of features used in comparing models overlap (e.g., first set of features being substrate processing systems 1-15 and second set of features being substrate processing systems 5-20). In some embodiments, hundreds of models are generated including models with various permutations of features and combinations of models.

At block 314, the system 300 performs model validation (e.g., via validation engine 184 of FIG. 1) using the validation set 304. The system 300 validates each of the trained models using a corresponding set of features of the validation set 304. For example, system 300 validates the first trained machine learning model using the first set of features in the validation set (e.g., substrate processing systems 1-10 and heat maps 61-80) and the second trained machine learning model using the second set of features in the validation set (e.g., substrate processing systems 11-20 and heat maps 61-80). In some embodiments, the system 300 validates hundreds of models (e.g., models with various permutations of features, combinations of models, etc.) generated at block 312. At block 314, the system 300 determines an accuracy of each of the one or more trained models (e.g., via model validation) and determines whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. The system 300 discards the trained machine learning models that have an accuracy that is below the threshold accuracy (e.g., based on the validation set).

At block 316, the system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow returns to block 312 where the system 300 performs model training using further refined training sets corresponding to further refined sets of features for determining a trained model that has the highest accuracy.

At block 318, the system 300 performs model testing (e.g., via testing engine 186 of FIG. 1) using the testing set 306 to test the selected model 308. The system 300 tests, using the first set of features in the testing set (e.g., operations 1-10 for products 81-100), the first trained machine learning model to determine the first trained machine learning model meets a threshold accuracy (e.g., based on the first set of features of the testing set 306). Responsive to accuracy of the selected model 308 not meeting the threshold accuracy (e.g., the selected model 308 is overly fit to the training set 302 and/or validation set 304 and is not applicable to other data sets such as the testing set 306), flow continues to block 312 where the system 300 performs model training (e.g., retraining) using different training sets corresponding to different sets of features (e.g., operations). Responsive to determining that the selected model 308 has an accuracy that meets a threshold accuracy based on the testing set 306, flow continues to block 320. In at least block 312, the model learns patterns in the historical data to make predictions and in block 318, the system 300 applies the model on the remaining data (e.g., testing set 306) to test the predictions.

At block 320, system 300 uses the trained model (e.g., selected model 308) to receive current property data 346 and current target performance data 356 (e.g., current property data 146 and current target performance data 156 of FIG. 1) and determines (e.g., extracts), from the trained model, predictive data 368 (e.g., predictive data 168 of FIG. 1) for heat transfer management to perform a corrective action. In some embodiments, the current property data 346 and current target performance data 356 corresponds to the same types of features in the historical property data 344 and historical target performance data 354. In some embodiments, the current property data 346 and current target performance data 356 corresponds to a same type of features as a subset of the types of features in historical property data 344 and historical target performance data 354 that is used to train the selected model 308.

In some embodiments, current data is received. In some embodiments, current data includes current heat transfer management data 366 (e.g., current heat transfer management data 166 of FIG. 1) and/or current property data 346 and current target performance data 356. In some embodiments, at least a portion of the current data is received from metrology equipment (e.g., metrology equipment 128 of FIG. 1) or via user input. In some embodiments, the model 308 is re-trained based on the current data. In some embodiments, a new model is trained based on the current heat transfer management data 366 and the current property data 346 and current target performance data 356.

In some embodiments, one or more of the blocks 310-320 occur in various orders and/or with other operations not presented and described herein. In some embodiments, one or more of blocks 310-320 are not be performed. For example, in some embodiments, one or more of data partitioning of block 310, model validation of block 314, model selection of block 316, and/or model testing of block 318 are not be performed.

FIGS. 4A-F are flow diagrams of methods 400A-F associated with heat transfer management, according to certain embodiments. In some embodiments, methods 400A-F are performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, methods 400A-F are performed, at least in part, by predictive system 110 and/or client device 120. In some embodiments, method 400A is performed, at least in part, by predictive system 110 (e.g., server machine 170 and data set generator 172 of FIG. 1, data set generator 272 of FIG. 2). In some embodiments, predictive system 110 uses method 400A to generate a data set to at least one of train, validate, or test a machine learning model. In some embodiments, one or more of methods 400B-D are performed by client device 120 (e.g., heat transfer management component 122). In some embodiments, method 400E is performed by server machine 180 (e.g., training engine 182, etc.). In some embodiments, method 400F is performed by predictive server 112 (e.g., predictive component 114). In some embodiments, a non-transitory storage medium stores instructions that when executed by a processing device (e.g., of predictive system 110, of server machine 180, of predictive server 112, etc.), cause the processing device to perform one or more of methods 400A-F.

For simplicity of explanation, methods 400A-F are depicted and described as a series of operations. However, operations in accordance with this disclosure can occur in various orders and/or concurrently and with other operations not presented and described herein. Furthermore, in some embodiments, not all illustrated operations are performed to implement methods 400A-F in accordance with the disclosed subject matter. In addition, those skilled in the art will understand and appreciate that methods 400A-F could alternatively be represented as a series of interrelated states via a state diagram or events.

FIG. 4A is a flow diagram of a method 400A for generating a data set for a machine learning model for generating predictive data (e.g., predictive data 168 of FIG. 1), according to certain embodiments.

Referring to FIG. 4A, in some embodiments, at block 402 the processing logic implementing method 400A initializes a training set T to an empty set.

At block 404, processing logic generates first data input (e.g., first training input, first validating input) that includes historical property data and historical target performance data.

At block 406, processing logic generates a first target output for one or more of the data inputs (e.g., first data input). In some embodiments, the first target output is historical heat transfer management data.

At block 408, processing logic optionally generates mapping data that is indicative of an input/output mapping. The input/output mapping (or mapping data) refers to the data input (e.g., one or more of the data inputs described herein), the target output for the data input (e.g., where the target output identifies historical heat transfer management data 164), and an association between the data input(s) and the target output.

At block 410, processing logic adds the mapping data generated at block 408 to data set T.

At block 412, processing logic branches based on whether data set T is sufficient for at least one of training, validating, and/or testing machine learning model 190 (e.g., uncertainty of the trained machine learning model meets a threshold uncertainty). If so, execution proceeds to block 414, otherwise, execution continues back to block 404. It should be noted that in some embodiments, the sufficiency of data set T is determined based simply on the number of input/output mappings in the data set, while in some other implementations, the sufficiency of data set T is determined based on one or more other criteria (e.g., a measure of diversity of the data examples, accuracy, etc.) in addition to, or instead of, the number of input/output mappings.

At block 414, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T.

After block 414, machine learning model (e.g., machine learning model 190) can be at least one of trained using training engine 182 of server machine 180, validated using validating engine 184 of server machine 180, or tested using testing engine 186 of server machine 180. The trained machine learning model is implemented by predictive component 114 (of predictive server 112) to generate predictive data (e.g., predictive data 168) for heat transfer management.

FIG. 4B is a method 400B associated with heat transfer management, according to certain embodiments.

At block 420 of method 400B, processing logic identifies property data associated with a substrate support system. The substrate support system may include components including one or more ceramic pucks (e.g., electrostatic chuck including clamp electrode and heaters, ceramic puck forming gas channels), a cooling plate (e.g., forming cooling channels), and bonding material bonding the one or more ceramic pucks and the cooling plate (e.g., bonding a first ceramic puck on a second ceramic puck and bonding the second ceramic puck on a cooling plate). The property data may include measurement data (e.g., height, width, thickness, channel height, channel width, corrugation protrusion height, corrugation protrusion width, corrugation protrusion period, etc.) of one or more components of the substrate support system.

In some embodiments, the property data includes sensor data received from one or more sensors associated with the substrate support system and/or simulated data associated with the substrate support system.

In some embodiments, the property data includes measurement data of one or more components of the substrate support system and/or processing chamber data of a processing chamber (e.g., the substrate support system being disposed in the processing chamber). In some embodiments, the processing chamber data includes one or more of flow rate data associated with process gas flowing into the processing chamber, venting port location data associated with a venting port of the processing chamber, and/or pressure data associated with pressure of the processing chamber.

At block 422, processing logic identifies target performance data associated with a substrate support system. In some embodiments, the target performance data includes one or more of a target heat map, a target etch map, or a target deposition map associated with an upper surface of the substrate support system. In some embodiments, the target performance data is associated with etch rate, deposition rate, uniformity (e.g., etch and/or deposition uniformity), and/or the like. In some embodiments, the target heat map is a substantially uniform heat map. In some embodiments, the target heat map is a substantially uniform heat map. In some embodiments, the target heat map includes a first portion that is at a first temperature and a second portion that is at a second temperature (e.g., intentionally asymmetric heat map).

At block 424, processing logic causes, based on the property data and the target performance data, heat transfer management of the substrate support system. In some embodiments, the processing logic determines heat transfer management data based on the property data and the target performance data and causes the heat transfer management based on the heat transfer management data. In some embodiments, the heat transfer management includes performance of one or more material operations (e.g., see block 434 of FIG. 4C). In some embodiments, the heat transfer management includes configuration of the substrate support system (e.g., see block 444 of FIG. 4D).

FIG. 4C is a method 400C associated with heat transfer management, according to certain embodiments.

At block 430, processing logic identifies property data associated with a substrate support system. This may be the same as or similar to block 420 of FIG. 4B.

At block 432, processing logic identifies target performance data associated with a substrate support system. This may be the same as or similar to block 422 of FIG. 4B.

At block 434, processing logic causes, based on the property data and the target performance data, performance of one or more material operations on the substrate support system. The one or more material operations may include one or more of: material removal from the substrate support system; material addition to the substrate support system; or surface processing of the substrate support system. In some embodiments, the material operations are performed on an upper surface of a cooling plate of the substrate support system. In some embodiments, the material operations are performed on interior surfaces that form cooling channels of the cooling plate of the substrate support system.

In some embodiments, the one or more material operations comprise causing the gas channels to one or more of have a variable gas channel width, have a variable gas channel height, or be configured to flow different gas composition types (e.g., helium (He), nitrogen (N₂), argon, etc.).

FIG. 4D is a method 400D associated with heat transfer management, according to certain embodiments.

At block 440, processing logic identifies property data associated with a substrate support system. This may be the same as or similar to block 420 of FIG. 4B.

At block 442, processing logic identifies target performance data associated with a substrate support system. This may be the same as or similar to block 422 of FIG. 4B.

At block 444, processing logic causes, based on the property data and the target performance data, the substrate support system to be configured. In some embodiments, block 444 includes determining, based on the property data and the target performance data, zone configuration data associated with the substrate support system and causing the substrate support system to be configured based on the zone configuration data. In some embodiments, causing the substrate support system to be configured based on the zone configuration data includes causing the substrate support system to be manufactured based on the zone configuration data (e.g., forming the channels, forming the zones of continuous heaters and pixelated heaters, etc.). In some embodiments, causing the substrate support system to be configured based on the zone configuration data includes causing the substrate support system to be controlled based on the zone configuration data (e.g., controlling duty, cycle, voltage, temperature, etc. of one or more of the heaters, such as continuous heaters and/or pixelated heaters).

FIG. 4E is a method 400E for training a machine learning model (e.g., model 190 of FIG. 1) for determining predictive data (e.g., predictive data 168 of FIG. 1) for heat transfer management.

Referring to FIG. 4E, at block 450 of method 400E, processing logic identifies historical property data. This may be the same as or similar to block 420 of FIG. 4B.

At block 452, processing logic identifies historical target performance data. This may be the same as or similar to block 422 of FIG. 4B.

At block 454, processing logic identifies historical heat transfer management data. The historical heat transfer management data may be indicative of one or more of historical material operations, historical zone configuration, historical zone manufacturing, historical zone control, and/or the like.

At block 456, processing logic trains a machine learning model using data input including historical property data and historical target performance data and target output including the historical heat transfer management data to generate a trained machine learning model. The determining of the heat transfer management data time (e.g., of block 424 of FIG. 4B) may be by using the trained machine learning model of FIG. 4C. In some embodiments, the trained machine learning model is a neural network.

FIG. 4F is a method 400F for using a trained machine learning model (e.g., model 190 of FIG. 1) for heat transfer management.

Referring to FIG. 4F, at block 460 of method 400F, processing logic identifies current property data. This may be the same as or similar to block 420 of FIG. 4B.

At block 462, processing logic identifies current target performance data. This may be the same as or similar to block 422 of FIG. 4B.

At block 462, processing logic provides the current property data and the current target performance data as input to a trained machine learning model (e.g., trained via block 456 of FIG. 4E).

At block 464, the processing logic receives, from the trained machine learning model, output associated with predictive data.

At block 466, the processing logic determines, based on the predictive data, current heat transfer management data. The current heat transfer management data may be indicative of one or more of current material operations, current zone configuration, current zone manufacturing, current zone control, and/or the like.

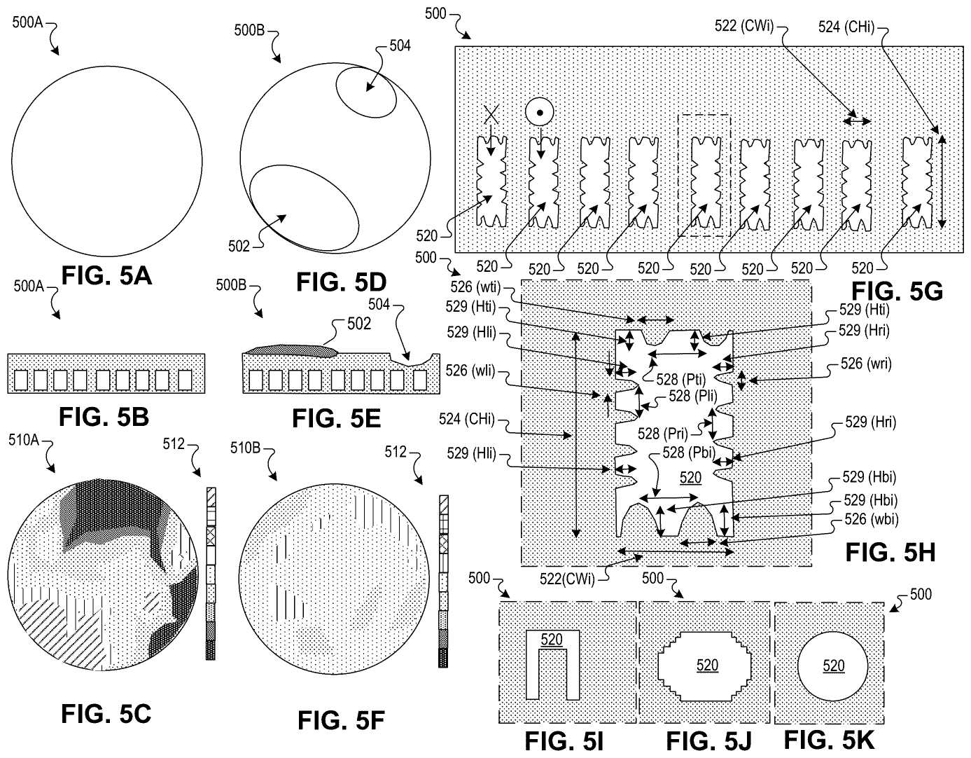

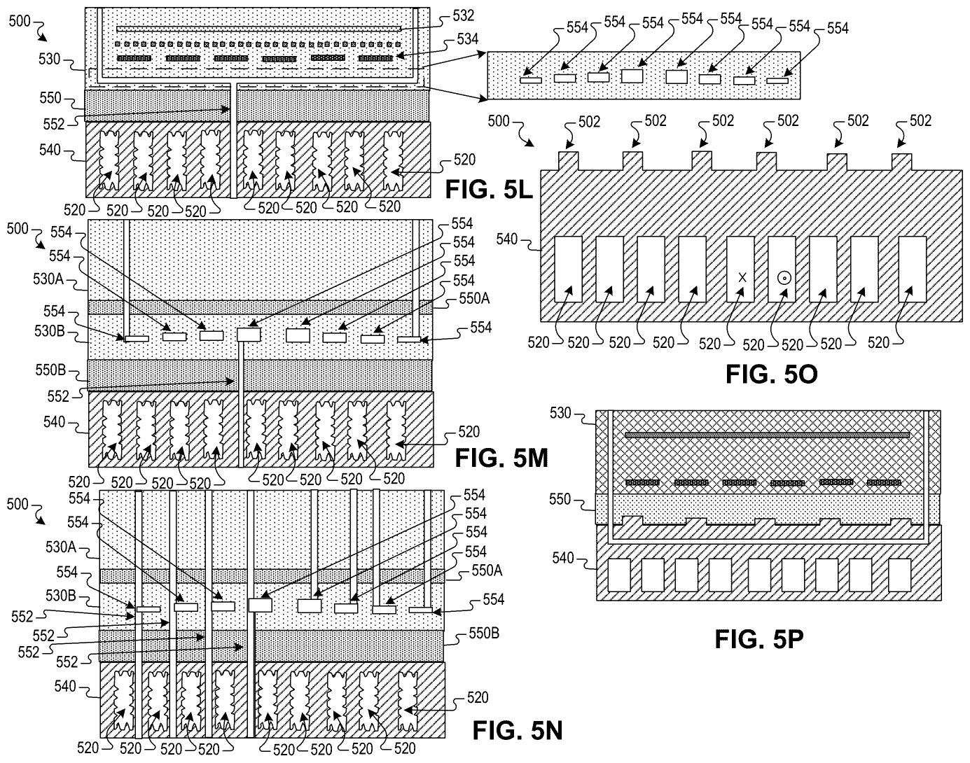

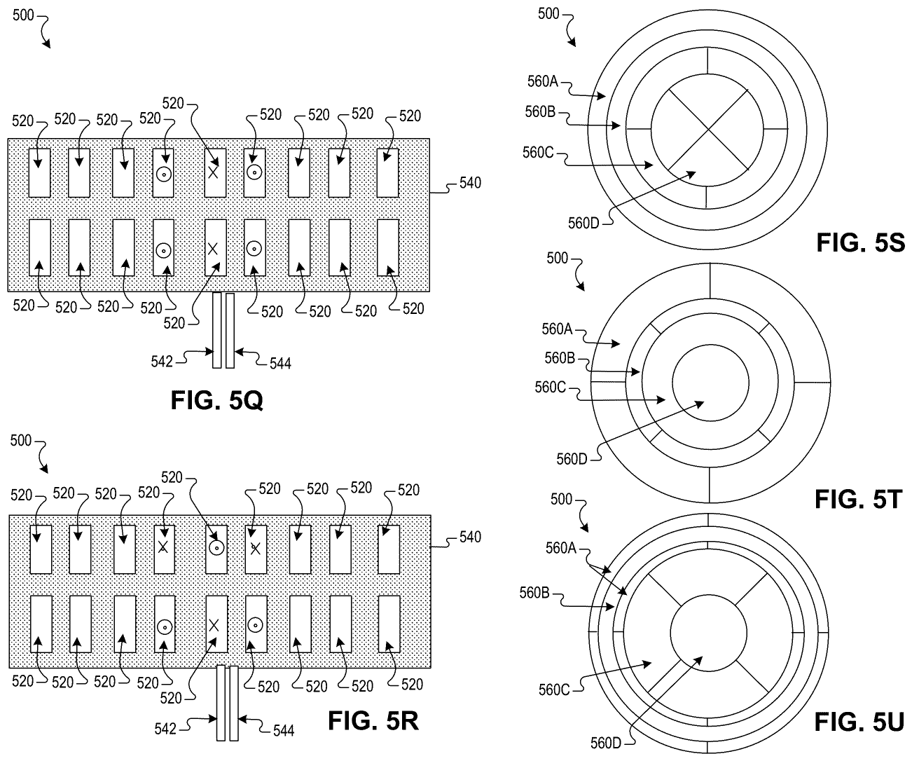

FIGS. 5A-U illustrate portions of substrate support systems 500 (e.g., substrate support system 125 of FIG. 1), according to certain embodiments.

The present disclosure may be associated with heat transfer management in substrate support systems (e.g., wafer support systems, electrostatic chuck (ESC), ESC stack). This may be done by modulating the heat transfer spatially across the substrate support systems without the use of complex and expensive multizone pixelated heater. The substrate support system may include layers (e.g., ceramic, bond material, baseplate) of uniform thickness. The substrate support system may form channels (e.g., gas channels and cooling channels that may be of uniform thickness. The present disclosure may modulate heat transfer coefficient spatially across the substrate support system to improve substrate thermal uniformity by one or more of: introducing corrugation in the channels; use of hybrid heaters; and/or incorporating layers of non-uniform thickness (e.g., asymmetric layers) with reduced symmetry.

Conventional systems have inadequate substrate thermal uniformity. This may be caused by inadequate heater transfer coefficient of the coolant to the cooling base due to smooth channels and/or radial heaters that are inadequate to compensate for azimuthal non-uniformity. The present disclosure may mitigate shortcomings of conventional systems by modulating heat transfer coefficient spatially across the substrate support system to improve wafer uniformity. This may be performed by one or more of: heat transfer management by channel engineering (e.g., FIGS. 5G-N); heat transfer modulation by incorporating intentional asymmetric features (e.g., FIGS. 5A-F, 5O-P); and/or heat transfer modulation by hybrid heaters (e.g., FIGS. 5S-U).

A substrate support system 500 may include a ceramic puck 530 that has a uniform thickness (e.g., and houses clamp electrode 532, heaters 534, and/or gas channels 552), a bond material 550 that is uniform and secures the ceramic puck 530 to the cooling plate 540, gas channels 552 that have a uniform thickness, and/or a cooling plate 540 that has a uniform thickness that forms embedded cooling channels 520.

FIGS. 5A-C illustrate views associated with a substrate support system 500A prior to undergoing material operations, according to certain embodiments. FIG. 5A illustrates an upper view of a component (e.g., cooling plate) of the substrate support system 500A. FIG. 5B illustrates a cross-sectional side view of a component (e.g., cooling plate) of the substrate support system 500A. FIG. 5C illustrates a heat map 510A associated with the substrate support system 500A (e.g., of the cooling plate, of an upper surface of the substrate support system, of a substrate disposed on the substrate support system, etc.). Key 512 illustrates temperature ranges from high (e.g., top of key 512) to low (e.g., bottom of key 512) of the heat map 510. In some embodiments, target performance data of the substrate support system 500 includes a heat map associated with the substrate support system 500 that is within a threshold range of temperatures (e.g., substantially the same temperature). In some embodiments, target performance data of the substrate support system 500 includes a heat map associated with the substrate support system 500 that substantially meets a desired heat map (e.g., substantially the same temperature, particular temperatures for different portions of the substrate support system and/or substrate, etc.). Substrate support system 500A may have a high thermal non-uniformity prior to material operations.

FIGS. 5D-F illustrate views associated with a substrate support system 500B subsequent to undergoing material operations, according to certain embodiments. In some embodiments, the material operations include material addition 502 and/or material removal 504.

Symmetry may be broken by one or more of: removing material from individual layer of the stack (e.g., ceramic puck, cooling plate); adding material (e.g., brazing aluminum to the machined ceramic puck or frit bonding ceramic to ceramic puck or a combination); and/or using dissimilar bond materials (e.g., use at least two bond materials with different thermal conductivities). In some embodiments, material may be added and/or removed based on statistical thermal unit signature. In some examples, removal of high conductivity metal from a cooling plate (e.g., with a corresponding increase in bonding material) may result in lower effective thermal conductivity (e.g., substrate temperature increases). In some examples, adding higher thermal conductivity material may increase the cooling (e.g., decreasing the fluid temperature). Low thermal non-uniformity may be reached by intentionally adding and/or removing material to alter the heat transfer coefficient.

In some embodiments, symmetry may be broken by removing material (e.g., by laser or mechanically) from a ceramic top surface facing substrate based on statical signature. In some embodiments, the removed material can include an isolated feature (e.g., pit) or a collection of features.

FIG. 5D illustrates an upper view of a component (e.g., cooling plate) of the substrate support system 500B. FIG. 5E illustrates a cross-sectional side view of a component (e.g., cooling plate) of the substrate support system 500B. FIG. 5F illustrates a heat map 510B associated with the substrate support system 500B (e.g., of the cooling plate, of an upper surface of the substrate support system, of a substrate disposed on the substrate support system, etc.). Key 512 illustrates temperature ranges from high to low of the heat map. In some embodiments, heat map 510B substantially meets target performance data of the substrate support system (e.g., within a threshold range of temperatures, substantially the same temperature, substantially meets a desired heat map, particular temperatures for different portions of the substrate support system and/or substrate, etc.). In some embodiments, substrate support system 500A (e.g., prior to material operations) does not meet the target performance data and substrate support system 500B (e.g., subsequent to material operations) meets the target performance data.

FIGS. 5G-K illustrate cross-sectional side views of substrate support systems 500 (e.g., cooling plates), according to certain embodiments.

Some conventional fluid channels are smooth. Fluid channels may be used for fluid flow (e.g., used for transporting liquid or gas). In some examples, liquid coolant flows in fluid channels in a cooling plate (e.g., metal machined cooling block). Gas flow may be via gas channels that are machined within the cooling plate (e.g., metal baseplate) and/or ceramic puck (e.g., ceramic workpiece) that is bonded to the cooling plate.

Conventionally, there may be inadequate heat transfer from the coolant to the cooling plate and/or inadequate transfer of heat from the substrate to the cooling plate (e.g., cooling base).

In some embodiments, the present disclosure introduces corrugations in the channels (e.g., cooling channels). The channels may be within the cooling plate (e.g., metal cooling plate), ceramic puck (e.g., ceramic workpiece), and/or an intermediate ceramic block that is bonded to the ceramic puck and the cooling plate (e.g., metal baseplate). In some embodiments, the channel cross-section is rectangular or a different shape.

Corrugations may perturb the fluid flow (e.g., cause turbulence) that results in increasing region for the fluid mixing and recirculation. The area near the corrugation may become more undisturbed. Perturbation may alter the Nusselt number and the friction factors that in turn modulates the heat transfer efficiency.

Corrugations (e.g., protrusions, recesses) may be defined by height (H), width (w), number of corrugations (e.g., i=0 to N). Multiple corrugations may be separated by a period (P). In some embodiments, corrugations include one or more of protrusions, recesses, surface texture, surface roughness, etc.

The corrugations may be present on one or more surfaces that form the channel. The number of corrugations on each surface may be different. The corrugations on opposite surfaces may not be aligned. The individual channel height (CH) and width (CW) may vary across the substrate support system. The corrugations may not be limited to rectangular cross-section.

In some embodiments, corrugations alter the thermos-hydro-dynamic characteristics of the fluid flow. The channels (e.g., gas channels, cooling channels) can be single or multiple zone with non-uniform heights. A channel (e.g., gas channel, cooling channel) may have at least one corrugation on either phase of the channel (e.g., flowing into the page, flowing out of the page). The corrugations may be periodic or aperiodic in height, in width, or both in height and width. A channel can carry a gas or a liquid. The channels may be part of the cooling plate (e.g., metal cooling base) and/or also be a part of the ceramic puck (e.g., ceramic plate bonded to the wafer support substrate).

In some embodiments, the substrate support system 500 (e.g., cooling plate) forms cooling channels 520. Fluid may go one direction through a first cooling channel 520 and the opposite direction in a second cooling channel 520. In some embodiments, the cooling channels 520 are corrugated (e.g., see FIGS. 5G-H). In some embodiments, the cooling channels 520 have a threshold surface roughness.

Referring to FIG. 5G, cooling channels 520 may be corrugated and may have a channel width 522 and a channel height 524. The “X” may indicate the fluid flows into the page and the circle with a dot in the middle may indicate the fluid flows out of the page.

Referring to FIG. 5H, cooling channels 520 may have different dimensions including one or more of channel width 522 (e.g., CWi), channel height 524 (CHi), protrusion width 526 (e.g., top protrusion width (wti), bottom protrusion width (wbi), left protrusion width (wli), right protrusion width (wri)), protrusion period 528 (e.g., top protrusion period (Pti), bottom protrusion period (Pbi), left protrusion period (Pli), right protrusion period (Pri)), and/or protrusion height 529 (e.g., top protrusion height (Hti), bottom protrusion height (Hbi), left protrusion height (Hli), right protrusion height (Hri)).

Referring to FIGS. 5I-K, substrate support system 500 may form one or more channels (e.g., cooling channels 520, gas channel 552).

The channels may be additively manufactured channels formed by: aluminum (Al) matrix with magnesium (Mg), silicon (Si) dopants (e.g., similar to Al6061); a metal matrix including particles; aluminum silicon carbide (Al—SiC) (e.g., matrix composite including an Al matrix with SiC particles); aluminum-carbon reinforced (e.g., carbon nanotube (CNT), nanotubes, etc.); ceramic/functional graded ceramic; and/or functionally graded metal-insulator matrix.

Channel (e.g., cooling channel 520, gas channel 552) cross-section may have at least one of a fin, a stepwise approximation to represent circular channel, a circular channel or a computer-generated regenerative channel (e.g., cooling fluid, such as compressed gas, expands in the channel to provide cooling). The cooling plate 540 may have cooling channels 520 and the gas channels 552.

Referring to FIG. 5I, in some embodiments, the cross-section of a cooling channel 520 may be a fin.

Referring to FIG. 5J, in some embodiments, the cross-section of a cooling channel 520 may be a stepwise approximation to represent a circular channel.

Referring to FIG. 5K, in some embodiments, the cross-section of a cooling channel 520 may be a circular channel.

FIGS. 5L-P illustrate cross-sectional side views of substrate support systems 500 (e.g., ESC stacks), according to certain embodiments.

Conventionally, an ESC stack may have a uniform cooling channel (e.g., with either gas channel and cooling channel in the cooling plate or gas channel the ceramic puck and the cooling channel in the cooling plate).

A substrate support system 500 may include a ceramic puck 530, a cooling plate 540, and bonding material 550 that bonds the ceramic puck 530 and cooling plate 540 together. The ceramic puck 530 may include a clamp electrode 532 and heaters 534 (e.g., electric resistive heaters, multi-zone heaters, four-zone heaters, etc.). Cooling plate 540 (e.g., baseplate) may form cooling channels 520, where fluid is to flow through the cooling channels 520 (e.g., to remove heat from the cooling plate 540). The substrate support system 500 may form gas channels 552 that flow through the cooling plate 540, bonding material, and ceramic puck 530 (e.g., to an upper surface of the substrate support system 500).

Referring to FIG. 5L, the gas channel 552 may form different sized branches 554 (e.g., variable gas channel width and/or height, with or without corrugations) that flow through the ceramic puck 530. In some embodiments, the branches 554 have substantially the same width and have varying heights. In some embodiments, branches 554 that are closer to the perimeter of the substrate support system 500 have lower heights and branches that are further from the perimeter (e.g., closer to the center) of the substrate support system 500 have greater heights. For substantially constant width of branches 554, increasing channel height of the branches 554 may lower the heat transfer efficiency compared to edge with higher heat transfer due to thinner channels.

Referring to FIGS. 5M-N, in some embodiments, substrate support system 500 includes a ceramic puck 530A, a ceramic puck 530B, and a cooling plate 540. The ceramic puck 530A and ceramic puck 530B may be bonded via bonding material 550A. The ceramic puck 530B may be bonded via bonding material 550B to cooling plate 540. The ceramic puck 530A may include a clamp electrode 532 and heaters 534. The cooling plate 540 may include cooling channels 520. The ceramic puck 530B may include branches 554 of gas channels 552 (e.g., gas channel layer).

Referring to FIG. 5M, the gas channel 552 may be directed through the cooling plate 540, through the bonding material 550B, into the ceramic puck 530B, then connect to different sized branches 554 formed by the ceramic puck 530B, through the bonding material 550A, and then through ceramic puck 530A to an upper surface of the substrate support system 500. This may be a one-zone gas channel.

Referring to FIG. 5N, multiple gas channels 552 may have trajectories through the cooling plate 540 (e.g., between cooling channels 520), through the bonding material 550B, to different sized branches 554 formed by the ceramic puck 530B, through the bonding material 550A, and then through ceramic puck 530A to an upper surface of the substrate support system 500. This may be a multi-zone gas channel (e.g., multi-zone gas channels passing through the cooling plate, the bonding material, and the ceramic puck).

In some embodiments, ceramic blocks 550A-B are a single ceramic block. In some embodiments, ceramic blocks 550A-B are more than two ceramic blocks that are joined via bonding material.

In some embodiments, a cooling plate 540 has a substantially flat surface. Referring to FIGS. 5O-N, in some embodiments, protrusions (e.g., metal protrusions, material additions 502) are formed on a cooling plate 540 has protrusions. In some embodiments, the protrusions (e.g., metal protrusions) are formed by machining the cooling plate 540 (e.g., the protrusions can be machined into the bulk of the cooling plate 540). In some embodiments, the protrusions (e.g., metal protrusions) are formed by adding material to and/or removing material from the cooling plate 540. In some embodiments, the protrusions are the same or different material than the material of the cooling plate 540. Having protrusions may increase the effective bond thermal conductivity to provide faster cooling.

Referring to FIG. 5O, an upper surface of a component (e.g., cooling plate 540) of substrate support system 500 may include material addition 502 (e.g., protrusions). The protrusions maybe non-uniform intentionally to enable desired thermal performance on an upper surface of the substrate support system 500.

Referring to FIG. 5P, a substrate support system 500 may include a cooling plate 540 that includes material addition 502 (e.g., protrusions) that interfaces with bonding material 550.

FIGS. 5Q-R illustrate cross-sectional side views of portions of substrate support systems 500 (e.g., cooling plates 540), according to certain embodiments.

In some embodiments, a cooling plate may have one channel. In some embodiments, a cooling plate 540 may have multi-layer channels (e.g., multiple rows of cooling channels 520, at least two levels of cooling channels 520). The coolant flow may be in the same direction or different directions for the multi-levels. The channel shape can be different (e.g., channels may not have a rectangular cross-section). The channels may have a common inlet 542 and a common outlet 544. The flow in multiple channels may be different.

In some embodiments, a cooling plate 540 has multiple rows of cooling channels 520 (e.g., a first row of cooling channels 520 above a second row of cooling channels 520). The “X” may indicate the fluid flows into the page and the circle with a dot in the middle may indicate the fluid flows out of the page.

Referring to FIG. 5Q, a cooling plate 540 may include cooling channels 520 above each other that have fluid that flows into the page (e.g., see cooling channels 520 with the indication of “X”) and cooling channels 520 above each other that have fluid that flows out of the page (e.g., see cooling channels 520 with the indication of a circle with a dot in the middle).

Referring to FIG. 5R, a cooling plate 540 may include cooling channels 520 above each other that have opposite flows (e.g., see cooling channels 520 with the indication of “X” above cooling channels 520 with the indication of a circle with a dot in the middle and vice versa).

FIGS. 5S-U illustrate upper views of substrate support systems 500, according to certain embodiments. In some embodiments, a zone can be annulus-shaped (e.g., a ring, has an outer circumference and an inner circumference), disc-shaped (e.g., substantially circular), or segment shaped (e.g., formed by different segments, multiple segments that form a ring or a disc, etc.).

Some electrostatic chucks may have microzone pixelated heaters and a multizone main heater in different planes. Pixelated heaters may be used to provide fine tuning (e.g., not the main heating power). Some electrostatic chucks may only have four-zone heaters.

The substrate support systems 500 of FIGS. 5S-U may be hybrid heaters (e.g., azimuthal distribution of heaters) that include continuous heaters and pixelated heaters. The continuous heaters and pixelated heaters may not be limited to the same plane. The continuous heaters and the pixelated heaters may overlap spatially. The pixelated heater may provide main heater and tuneability. In some embodiments, the pixelated heaters provide tuneability and primary heating and the continuous heaters provide secondary heating.

A substrate support system 500 may have different portions 560 (e.g., portions 560 of upper surface). For example, a substrate support system 500 may have an outer portion 560A, mid-outer portion 560B, mid-inner portion 560C, and an inner portion 560D. Each of the portions 560 may have one or more heating zones configured for temperature tuning. In some embodiments, one or more of the portions 560 may be further divided into additional heating zones (e.g., via pixelated heaters).

Referring to FIG. 5S, a substrate support system 500 may include an outer portion 560A that is a continuous heater, mid-outer portion 560B that is a continuous heater, mid-inner portion 560C that is a pixelated heater (e.g., four heaters), and an inner portion 560D that is a pixelated heater (e.g., four heaters). As shown in FIG. 5S, center pixelated heater zones (e.g., X>1) may be surrounded by Z (>1) set of annular heater zones.

Referring to FIG. 5T, a substrate support system 500 may include an outer portion 560A that is a pixelated heater (e.g., four heaters), mid-outer portion 560B that is a pixelated heater (e.g., four heaters), mid-inner portion 560C that is a continuous heater, and an inner portion 560D that is a continuous heater. As shown in FIG. 5T, center circular heater may be surrounded by X (>1) annular heater zones surrounded by Z (>1) pixelated heaters.

Referring to FIG. 5U, a substrate support system 500 may include an outer portion 560A that is a pixelated heater (e.g., four heaters), mid-outer portion 560B that is a continuous heater and overlaps a mid-portion of the outer portion 560A, mid-inner portion 560C that is a pixelated heater (e.g., four heaters), and an inner portion 560D that is a continuous heater. As shown in FIG. 5T, there may be alternating pixelated and continuous heater zones.

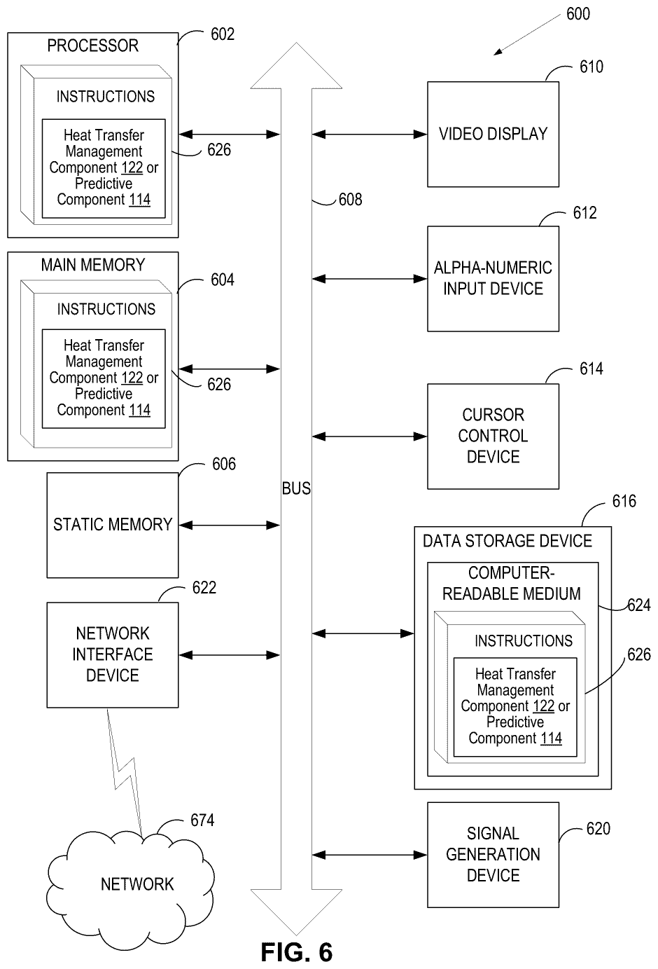

FIG. 6 is a block diagram illustrating a computer system 600, according to certain embodiments. In some embodiments, the computer system 600 is one or more of client device 120, predictive system 110, server machine 170, server machine 180, or predictive server 112.

In some embodiments, computer system 600 is connected (e.g., via a network, such as a Local Area Network (LAN), an intranet, an extranet, or the Internet) to other computer systems. In some embodiments, computer system 600 operates in the capacity of a server or a client computer in a client-server environment, or as a peer computer in a peer-to-peer or distributed network environment. In some embodiments, computer system 600 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 includes a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 616, which communicate with each other via a bus 608.

In some embodiments, processing device 602 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 600 further includes a network interface device 622 (e.g., coupled to network 674). In some embodiments, computer system 600 also includes a video display unit 610 (e.g., an LCD), an alphanumeric input device 612 (e.g., a keyboard), a cursor control device 614 (e.g., a mouse), and a signal generation device 620.

In some implementations, data storage device 616 includes a non-transitory computer-readable storage medium 624 on which store instructions 626 encoding any one or more of the methods or functions described herein, including instructions encoding components of FIG. 1 (e.g., heat transfer management component 122, predictive component 114, etc.) and for implementing methods described herein.

In some embodiments, instructions 626 also reside, completely or partially, within volatile memory 604 and/or within processing device 602 during execution thereof by computer system 600, hence, in some embodiments, volatile memory 604 and processing device 602 also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as application-specific integrated circuits (ASICs), field programmable gate arrays (FPGAs), digital signal processors (DSPs), or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “identifying,” “causing,” “adding,” “removing,” “processing,” “providing,” “obtaining,” “determining,” “training,” “predicting,” “receiving,” “updating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method comprising:
identifying property data associated with a substrate support system;
identifying target performance data associated with the substrate support system;
determining, based on the property data and the target performance data, zone configuration data associated with the substrate support system; and
causing the substrate support system to be configured based on the zone configuration data.

2. The method of claim 1, wherein the property data comprises one or more of:
sensor data received from one or more sensors associated with the substrate support system; or
simulated data associated with the substrate support system.

3. The method of claim 1, wherein the causing of the substrate support system to be configured based on the zone configuration data comprises causing the substrate support system to be manufactured based on the zone configuration data.

4. The method of claim 1, wherein the zone configuration data is associated with a plurality of zones of the substrate support system, the plurality of zones comprising one or more of an annulus-shaped zone, a disc-shaped zone, or a segment-shaped zone.

5. The method of claim 1, wherein the causing of the substrate support system to be configured based on the zone configuration data comprises causing the substrate support system to be controlled based on the zone configuration data.

6. The method of claim 1, wherein the property data comprises one or more of:
measurement data of one or more components of the substrate support system; or
processing chamber data of a processing chamber, the substrate support system being disposed in the processing chamber, the processing chamber data comprising one or more of flow rate data associated with process gas flowing into the processing chamber, venting port location data associated with a venting port of the processing chamber, or pressure data associated with pressure of the processing chamber.

7. The method of claim 1, wherein the target performance data comprises one or more of a target heat map, a target etch map, or a target deposition map associated with an upper surface of the substrate support system.

8. The method of claim 1 further comprising:
providing the property data and the target performance data as input to a trained machine learning model;
obtaining, from the trained machine learning model, output associated with predictive data; and
determining, based on the predictive data, the zone configuration data to cause the substrate support system to meet the target performance data.

9. The method of claim 8, the trained machine learning model being trained based on data input comprising historical property data and historical target performance data of historical substrate support systems and target output comprising historical zone configuration data associated with the historical substrate support systems.

10. The method of claim 1, wherein the substrate support system comprises:
a ceramic puck that one or more of: houses a clamp electrode; houses heaters; or forms gas channels;
a cooling plate forming cooling channels and gas channels; and
a bonding material coupling the ceramic puck to the cooling plate.

11. The method of claim 1, wherein the substrate support system comprises a hybrid heater system comprising a plurality of heaters, a first subset of the plurality of heaters being continuous heaters and a second subset of the plurality of heaters being pixelated heaters.

12. The method of claim 11, wherein the plurality of heaters comprises a first heater in a first plane and a second heater in a second plane that is different from the first plane.

13. The method of claim 11, wherein at least a portion of the plurality of heaters overlap spatially.

14. The method of claim 11, wherein the pixelated heaters provide tuneability and primary heating, and wherein the continuous heaters provide secondary heating.

15. A non-transitory machine-readable storage medium storing instructions which, when executed cause a processing device to perform operations comprising:
identifying property data associated with a substrate support system;
identifying target performance data associated with the substrate support system;
determining, based on the property data and the target performance data, zone configuration data associated with the substrate support system; and
causing the substrate support system to be configured based on the zone configuration data.

16. The non-transitory machine-readable storage medium of claim 15, wherein the causing of the substrate support system to be configured based on the zone configuration data comprises causing the substrate support system to be manufactured based on the zone configuration data.

17. The non-transitory machine-readable storage medium of claim 15, wherein the causing of the substrate support system to be configured based on the zone configuration data comprises causing the substrate support system to be controlled based on the zone configuration data.

18. A system comprising:
a memory;
a processing device coupled to the memory, the processing device to:
identify property data associated with a substrate support system;
identify target performance data associated with the substrate support system;
determine, based on the property data and the target performance data, zone configuration data associated with the substrate support system; and
cause the substrate support system to be configured based on the zone configuration data.

19. The system of claim 18, wherein to cause the substrate support system to be configured based on the zone configuration data, the processing device is to cause the substrate support system to be manufactured based on the zone configuration data.

20. The system of claim 18, wherein to cause the substrate support system to be configured based on the zone configuration data, the processing device is to cause the substrate support system to be controlled based on the zone configuration data.
